(19) United States
(12) Patent Application Publication
(10) Pub. No.: US 2017/0323885 A1
(43) Pub. Date: Nov. 9, 2017

(54) HIGH QUALITY VARACTOR

(71) Applicant: North Carolina State University, Raleigh, NC (US)

(72) Inventor: Wallace Shepherd Pitts, Raleigh, NC (US)

(21) Appl. No.: 15/490,843

(22) Filed: Apr. 18, 2017

Related U.S. Application Data
(60) Provisional application No. 62/324,035, filed on Apr. 18, 2016.

(51) Int. Cl. H01L 27/08; H01L 21/02; H01L 29/93

(52) U.S. Cl. CPC H01L 27/0808; H01L 29/93; H01L 21/02488; H01L 21/02505; H01L 21/02521

(57) ABSTRACT

Various examples are provided for varactors (variable capacitors). Described are both simple and complex forms of variable capacitors and improvements thereof. The varactor can be sufficiently small (narrow) to be isolated on a chip as a single or plurality of devices. Devices may be expanded using multiple varactors. In addition, various varactors can further be improved by the inclusion of a thin material to reduce the resistance of the varactor device. Diodes may also be implemented using the disclosed forms.

### CROSS REFERENCE TO RELATED APPLICATIONS

This application claims priority to, and the benefit of, co-pending U.S. provisional application entitled “High Quality Varactor” having Ser. No. 62/324,035, filed Apr. 18, 2016, which is hereby incorporated by reference in its entirety.

### STATEMENT REGARDING FEDERALLY SPONSORED RESEARCH OR DEVELOPMENT

This invention was made with government support under agreement FA8650-09-C-1504 awarded by the the United States Air Force Research Laboratory and agreement 0811582 awarded by the National Science Foundation. The Government has certain rights in the invention.

### BACKGROUND

Varactors (Variable Capacitors) have been used as tunable elements in radios for some time. However, there are certain challenges in improving the quality of varactors especially as energy efficiency and frequencies are improved. For example, the quality of a varactor is based on the energy that is lost due to things like resistance in the varactor. This can limit the maximum frequency range, application space, and broad range frequency agile radios.

### SUMMARY

Embodiments of the present disclosure are related to variable capacitors (varactors). In one aspect, among others, a varactor comprises a first conductive electrode; a semiconductor formed over the first conductive electrode; an insulator formed over the semiconductor; and a second conductive electrode formed over the insulator. In another aspect, a varactor comprises a semiconductor formed over a first insulator; a second insulator formed over the semiconductor; and a conductive electrode formed over the insulator. In another aspect, a varactor comprises a conductive electrode; a thin material formed over the conductive electrode; the thin material configured to reduce the series resistance of the varactor; and a semiconductor formed over the thin material.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a graphical representation and lumped element model of an example of a MISM (metal-insulator-semiconductor-metal) varactor, in accordance with various embodiments of the present disclosure.

FIGS. 2-4 illustrate various characteristics of the MISM varactor of FIG. 1, in accordance with various embodiments of the present disclosure.

FIG. 5 is a graphical representation of the lumped element model of the MISM varactor of FIG. 1, in accordance with various embodiments of the present disclosure.

FIG. 6 illustrates the gain (K) and quality factor (Q) of the MISM varactor of FIG. 1, in accordance with various embodiments of the present disclosure.

FIGS. 7A and 7B are graphical representations and lumped element models of examples of floating body varactors (FBVs), in accordance with various embodiments of the present disclosure.

FIG. 8 is a graphical representation of the lumped element model of the FBV of FIG. 7A, in accordance with various embodiments of the present disclosure.

FIG. 9 illustrates the gain (K) and quality factor (Q) of the FVB of FIG. 7A, in accordance with various embodiments of the present disclosure.

FIGS. 10A-10D illustrate examples of GSG (ground signal ground) probe structures used for varactor testing, in accordance with various embodiments of the present disclosure.

FIGS. 11, 12A, 12B, 13, 14A and 14B illustrate various characteristics of the MISM varactor of FIG. 1 and FBV of FIGS. 7A and 7B, in accordance with various embodiments of the present disclosure.

FIG. 15 is a graphical representation of an example of a MISM varactor with a very thin material region, in accordance with various embodiments of the present disclosure.

FIGS. 16A-16E are graphical representations of examples of diodes based upon varactor configurations, in accordance with various embodiments of the present disclosure.

### DETAILED DESCRIPTION

Disclosed herein are various embodiments related to varactors (variable capacitors). Reference will now be made in detail to the description of the embodiments as illustrated in the drawings, wherein like reference numbers indicate like parts throughout the several views.

A new form of CMOS integrable varactor, MISM (metal-insulator-semiconductor-metal), is presented, designed, fabricated and tested out to 20 GHz. Several different semiconductor materials and deposition techniques can be used to deposit the active region at various processing temperatures of the device with varying degrees of success. Working devices were fabricated at room temperature up to 155° C. This device differs from that of other varactors in that the topology comprises two parallel metal plates that are of the same relative size to conserve space and thus the series resistance (Rₛ) becomes the dominating factor in determining the Q of the varactor. Specific focus is given to reducing the Rₛ of the device for this topology.

A new device topology, called a FBV (floating body varactor)—due to the body “floating” between the two oxides and electrodes—is introduced. This eliminates one of the major problems in varactors, contact resistance, by building a metal-insulator-semiconductor-insulator-metal (MISIM). The FBV can be realized by combining two of the aforementioned varactors and mating them bulk to bulk vertically. This creates a sandwiched semiconductor active region and eliminates the required bulk contact of a different material. A bulk contact introduces a series contact resistance (R_{c}) that is dominated by the work function of the metal contacts as well as the fermi-level of the semiconductor region. Additionally, the FBV can be built in a vertically integrated varactor stack up. Meaning, that multiple varactors can be stacked in between the top and bottom gate electrodes. This may increase the operating voltages of the varactor. Finally, the high R_{c} can be used as an advantage by directly contacting the semiconductor region through a small high resistance contact area. This high R_{c} could be used as a tuning port to the FBV. Additionally, the “floating body” of the varactor may be further leveraged by tunneling electrons onto the “floating” body of the varactor to be used as a tuning node as there is no consumed DC current.

High quality varactors can be created on any substrate. This means, for the first time high quality varactor devices can be realized on thin-film transistor (TFT) which is a required building block for an inbuilt RF functionality.

In this work, the use of a self-limiting silicide layer, such as Zirconium Silicide (ZrxSix) due to the low temperature formation of the silicide, allows the R_{c} to be significantly reduced which allows for significant improvements to the overall Q of a MISM varactor. This allows the integration of the device on-chip as it would not need a “sufficiently large” gate in contact with the semiconductor layer. This is important to the scalability of the varactor device.

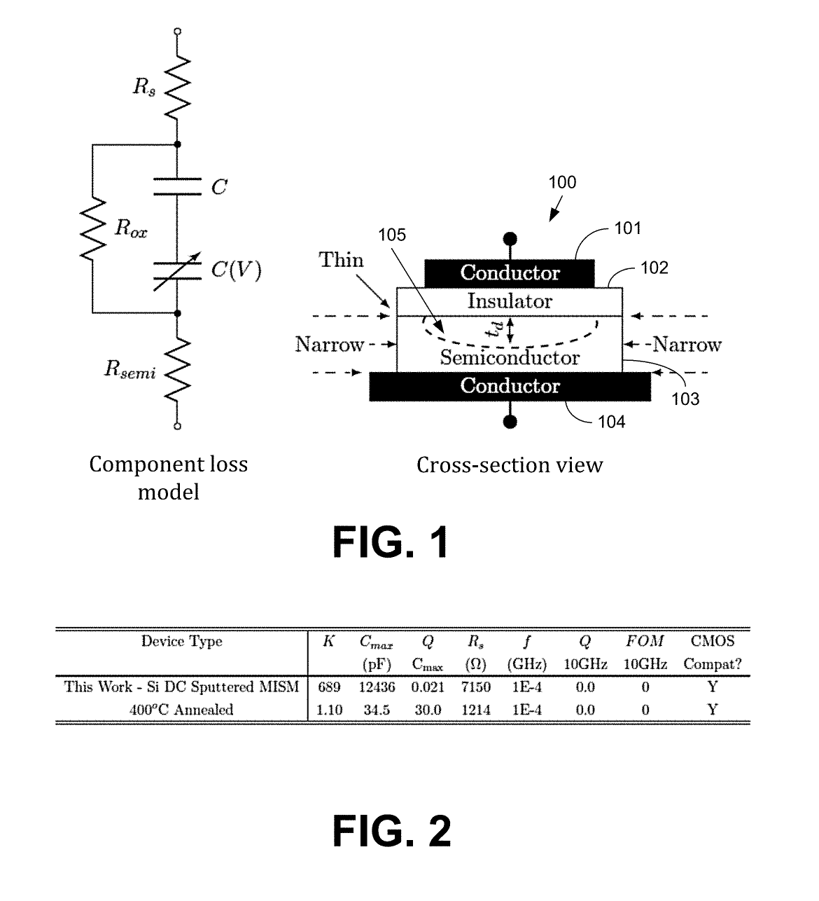

Referring to FIG. 1, shown is an example of a MISM (metal-insulator-semiconductor-metal) varactor 100, which includes a first conductor layer 101 disposed on an insulator layer 102, which is itself disposed on a semiconductor layer 103 that is disposed on a second conductor layer 104. The conductor layers 101 and 104 can comprise metal or other conductive material as appropriate. The MISM varactor 100 can be built in modern processes and can improve the quality factor over existing varactor technologies (MEMs, tunable dielectrics, etc.) where conductor layers 101 and 104 are sufficiently small (narrow) to be isolated on a chip as a single or plurality of devices. The depletion/accumulation region 105 of the device allows the device to vary the capacitance. A voltage bias is applied to the control gate of the device causing the semiconductor to become depleted and in turn increasing the effective distance—and thus the K—between the top and bottom gates 101 and 104.

These MISM varactors can be fabricated using a variety of methods. A commonality of each of the devices in this disclosure was that all the devices had a metal bottom gate that was deposited onto an insulated substrate. The type of metals that were deposited varied based on the needs of the material stack, such as forming a silicide layer. For example, a Ultra High Vacuum Rapid Thermal Chemical Vapor Deposition (UHV-RTCVD) system can be used to deposit Silicon Germanium (SixGex). A Radio Frequency Sputter Deposition (RFSD) system can also be used to deposit a Doped Si onto an Aluminum (Al) layer with a very thin Zirconium (Zr) layer which were both deposited by Direct Current Sputter Deposition (DC Sputtered).

Virtually any type of conductive material can be used for electrodes, any type of insulator can be used as a gate oxide, and any semiconductor material can be used for the active device region. Low temperature semiconductor materials such as, e.g., Indium Gallium Zinc Oxide (IGZO) and Aluminum Zinc Oxide (AZO) can be used in low temperature TFT devices. Gate oxide materials that can be used include, e.g., HfO₂, Al₂O₃, TiO₂, ZrO₂, Si₃N₄, etc.

Devices were fabricated on both a 75 mm and 100 mm Si wafer that has 1 μm of SiO₂ to isolate the devices from the conductive substrate. The Si wafer was used solely as a carrier substrate for these devices. The first layer was a blanket metal layer deposition that would form the bottom gate contact. It was deposited using the DC Sputtered method on a silicon wafer that has a 1 μm SiO₂ layer. Next an electrical insulation layer, the gate oxide, was then deposited using an atomic layer deposition (ALD) system. The ALD system allows for a mono-layer of material to grow for each reaction in the chamber. The reaction was induced by flowing a limited amount of a precursor into the chamber which created a very thin and conformal chemical coating on the wafer. Next, a second chemical precursor was flown into the system where it reacted forming the mono-layer. The ALD then performed multiple cycles to achieve the desired thickness of the layer. The result was a high quality and uniform film. Then a photolithography process occurred to create a contact cut through the insulator which enabled the connection of the bottom gate of the device to a Ground Signal Ground (GSG) probe for high frequency measurements. Additionally, this created the gate to bottom short that was needed for de-embedding at high frequencies. Without a contact cut, a capacitor would have been formed and the measured device would have been open circuit.

The photolithography process comprised spinning on an Ultra Violet (UV) sensitive photoresist resin, such as Shiply 1813. The Headway spin coater was used to spin coat the wafer with the photoresist at a high speed forming a 1.5 μm thick layer. Next a Karl Suss MA6 Top Side Mask Aligner (MA6) was used to transfer the “photo pattern” from the mask onto the UV sensitive resin using a high intensity UV lamp and wafer alignment stage. The exposed photoresist was then removed, or “developed,” by using a developer solution. The developer leaves regions of the surface of the wafer covered by the photoresist, much like black and white areas of a photograph, depending on if that region was exposed to the UV light or not. Thus, the exposed portions of the wafer can be subjected to chemical processing such as etching or a lift-off process. In this case, a dry etch (which uses a chemical plasma to remove material) was used to remove the oxide material from the exposed areas. Then, the remaining photoresist was removed, using a chemical solvent to leave behind a clean surface that is ready for the next material in the process.

This next area was the active device area. For generation of the devices a lift-off technique was used. This means that the photolithography process with an alignment to the previous mask is first completed, followed by depositing the desired material on top of the photoresist and exposed areas. This is a low temperature and non-conformal materials deposition as the photoresist is temperature sensitive and the solvent solution that strips the photoresist off has to be able to come in contact with the photoresist. A conformal process can trap the photoresist underneath a material layer protecting it from the chemical. The liftoff technique was completed leaving behind the material deposited only in the desired exposed areas. Finally, the top gate material was deposited onto the wafer, a photolithography was once again completed and the excess material was removed using a wet etch process.

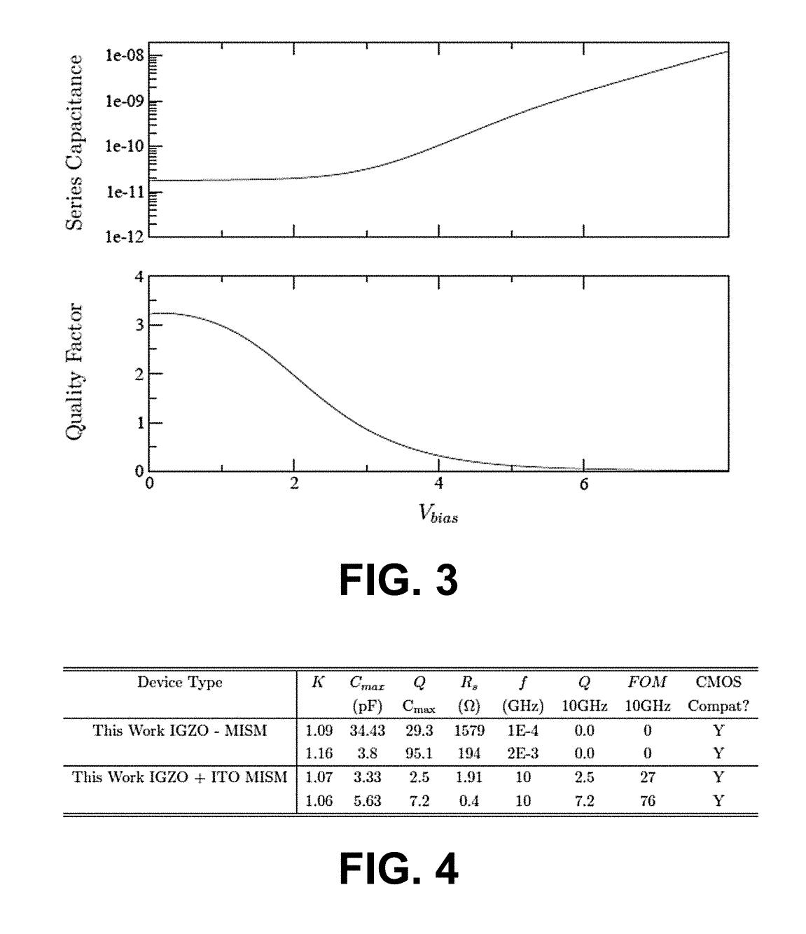

Using an Agilent E4980A 20 Hz-2 MHz Precision LCR Meter (LCR Meter) and a high frequency GSG probe, the DC sputtered a-Si varactors were tested and extracted at 100 kHz. The table in FIG. 2 illustrates results of the a-Si measured low and high frequency varactors. The probe was de-embedded using an on die “short” and “open” circuit calibration devices. This allowed for an accurate measurement of the Device Under Test (DUT). FIG. 3 illustrates the a-Si MISM varactor Quality Factor and Series Capacitance at 100 kH. Since the device has a very large K at low frequency, it may be inferred that by increasing the conductance (such as increasing the doping concentration) a higher quality but lower K device can be built. To improve the Q of the varactor, the wafer was annealed at 400° C. for three minutes. This temperature was chosen to keep the process CMOS friendly and to improve the contact resistivity (ρ_{c}) and the bulk resistivity (ρₛ). This did work, and a significant improvement was made to the Q of the device by sacrificing K. This first-pass fabrication validated the concept, but indicated the need for further optimization (specifically the Rₛ) in order to yield a higher Q varactor.

Next, a higher Q device was built and tested that used IGZO as the active semiconductor region. As these devices utilized the same mask set as the a-Si varactor, the testing methodologies were exactly the same. The IGZO recipe and equipment used were at 5 mTorr of O₂. This had a measured sheet resistance of 5.1 k for a 15 nm thick IGZO layer. Using the a Mobility of 1 6cm2/V·sec, the doping concentration was determined to be 4.55E+19 cm⁻³. This was in reasonable agreement with the published results. The Q of these devices were significantly better than the a-Si varactors, which can be attributed to the increased ρₛ and decreased ρ_{c} due to the increased doping concentration. The minimum capacitance (Cₘᵢₙ) was measured to be 30 pF which is close to the ideally modeled amount. However, the maximum capacitance (Cₘₐₓ) was measured to be 34 pF which translates to a K of 1.086 to 1.117 at 2 MHz, and this value is much lower than expected/predicted K of 1.62. This decrease in K is likely due to a breakdown of the HfO₂ oxide at 2.8 Vdc before the entire change in capacitance could be extracted. This seems to be a premature breakdown as HfO₂ has a breakdown voltage of about 0.55 V/nm and the desired oxide thickness was about 12 to 15 nm-or 6.6 to 8.25 Vdc. This may be attributed to some other physical failure of probing or manufacturing of the device.

A second set of IGZO varactors were fabricated using the same process as above except for an added Indium Tin Oxide (ITO) inter-facial layer to the IGZO layer to act a degenerately doped interface for the varactor electrodes. ITO is commonly used as a contact electrode to IGZO devices and the process could be implemented in the same step without breaking vacuum. The result was an improvement of several orders of magnitude of the devices Q. The table in FIG. 4 illustrates results of the measured low and high frequency varactors. If the Q values are converted from 10 GHz (Q of 2.5 to 7.2) to a Q at 2 MHz from 12550 to 35750 which is more than a two order of magnitude improvement. This may be attributed to a reduced ρ_{c} and even possibly due to an increased familiarity with the recipe for varactor fabrication.

The first Generation devices, while working with a tuning range of over 650:1, still exhibited a low quality factor (Q<1 at 100 kHz). Improvements in Q came from substituting an IGZO deposited by Pulsed Laser Deposition (PLD) for the DC Sputtered Si layer. The IGZO layer showed to have controllable doping concentrations that could yield higher Q results (Q>28 at 100 kHz 1.15:1 tuning range). While working devices were fabricated using the first generation masks, the deposited IGZO film had large and visible particles. These particles are a known byproduct of PLD depositions and are also known to be insulative in nature. Additionally, the film uniformity across the wafer is hard to control for PLD even though the tool may have a maximum capacity of a small single 75 mm wafer. A second Generation of masks were developed utilizing a Co-planer Wave Guide (CPVV) probe structure. This proved to be a much more robust probing structure than the first Generation devices.

The second Generation of devices were fabricated using ALD of AZO as the semiconductor and ALD of Al2O3 as the oxide layer. These materials were deposited at the same time without breaking vacuum. Additionally, these layers were deposited directly on a Titanium Gold (TiAu), where Au was in direct contact with the Al₂O₃ and Ti was used as an adhesion layer stack which minimized any intra-layer oxides in the device. The measured results yielded Qs in the 1000s for low frequencies and Q up to 80 for 10 GHz. While a notable improvement was observed over the preceding designs; however, the K of the device was only 1.32:1 in the best case measurement.

With varactor technologies, there is a design tradeoff between Q and K. To increase the K of the device, one can either change the fixed capacitance (C_{fixed}) and/or the variable capacitance (C_{variable}). In Equation 4.3, C_{fixed} can be manipulated through either changing doping concentrations, such as in diode varactors, or oxide thickness, such as in MOS varactors. If the designer wishes to increase K by increasing the fixed capacitance, done through t_{fixed}, it will adversely affect the Q of the device, due to the decrease in the Reactance (Xₛ) term in Equation 4.5. If the designer wishes to increase the Q of the varactor through decreasing the variable capacitance then the materials properties that are changed will increase the Rₛ. For example, an AJD will decrease the doping concentration in the semiconductor region which decreases the ρₛ and thus increases the ρₛ. The higher the Q of the device, the more efficient the device is, and the higher the K of the device, the more frequency-agile it is. This interaction limits the ability to make a wide frequency amplifier for wireless devices.

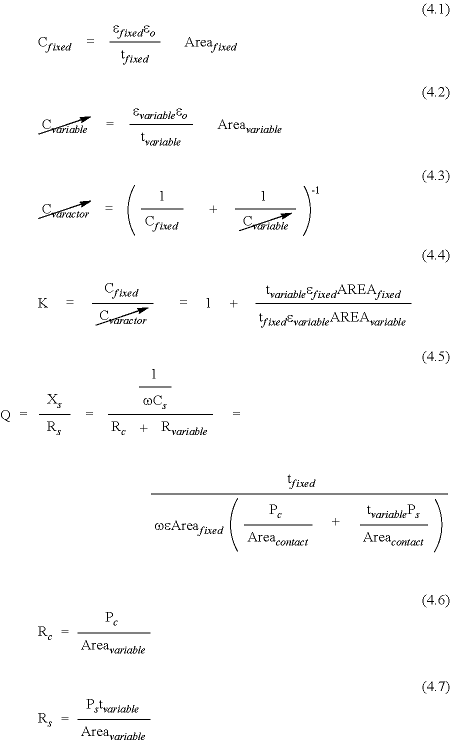

There is also a tradeoff between packaging high Q varactors off-chip or integrating lower Q varactors on-chip to eliminate matching networks and other channel degradations due to impedance, capacitance, and resistance of the connection. Off-chip varactors increase the overall cost, narrow the frequency response, and increase the overall area of the solution. The ideal system would integrate a high Q and high K varactor into a traditional CMOS process. This would afford the designer the best of both worlds and lend itself to a frequency-agile and high performance design. However, most forms of varactors cannot be directly integrated on-chip due to thermal processing requirements. This leaves the only method for integration as flip-chip bonding such as WSpry or CMOS varactor technologies. Standard CMOS technologies have a maximum temperature and time at temperature that a chip can be subjected to, before it adversely affects the design. For example, standard CMOS interconnect is made out of Al; Al has a melting temperature of 450° C. Most post processing steps on standard CMOS technology need to be performed at sub 400° C. and there are guidelines for the maximum amount of time elevated temperatures can be tolerated (30-90min depending on the process).

Parasitics in the varactor can also impact performance. For example, Rₛ can be a problem with varactors other than tunable dielectric material (TDM) varactors. Other varactor technologies often create a contact between two dissimilar materials (e.g., metal and a semiconductor material), so good quality ohmic contacts to the varactor are used to allow the device to be degenerately doped. Degenerately doping these regions decreases the tunability of the varactor even in cases where a gradient doping scheme is used.

The Rₛ accounts for numerous components: interconnects, top gate, bottom gate, oxide leakage, bulk material, and R_{c}. All of these components contribute to the total Rₛ of the varactor. The lower the Rₛ the higher the Q, as can be seen from Equation 4.5. While there are multiple terms that add up to the varactor's Rₛ, the dominant form of resistance of the device is typically the R_{c} and the bulk material resistance. The other parasitic resistances can be engineered around by choosing a low-loss oxide, matching networks, keeping the interconnects as short as possible, and using thick metal layers. In some cases ρ_{c} can be made negligible by degenerately doping the interface between the semiconductor region and metal and/or making the interface area very large. However, in cases where the rest of the varactor's series resistances have been significantly minimized, such as in the MISM varactor, it can be significant.

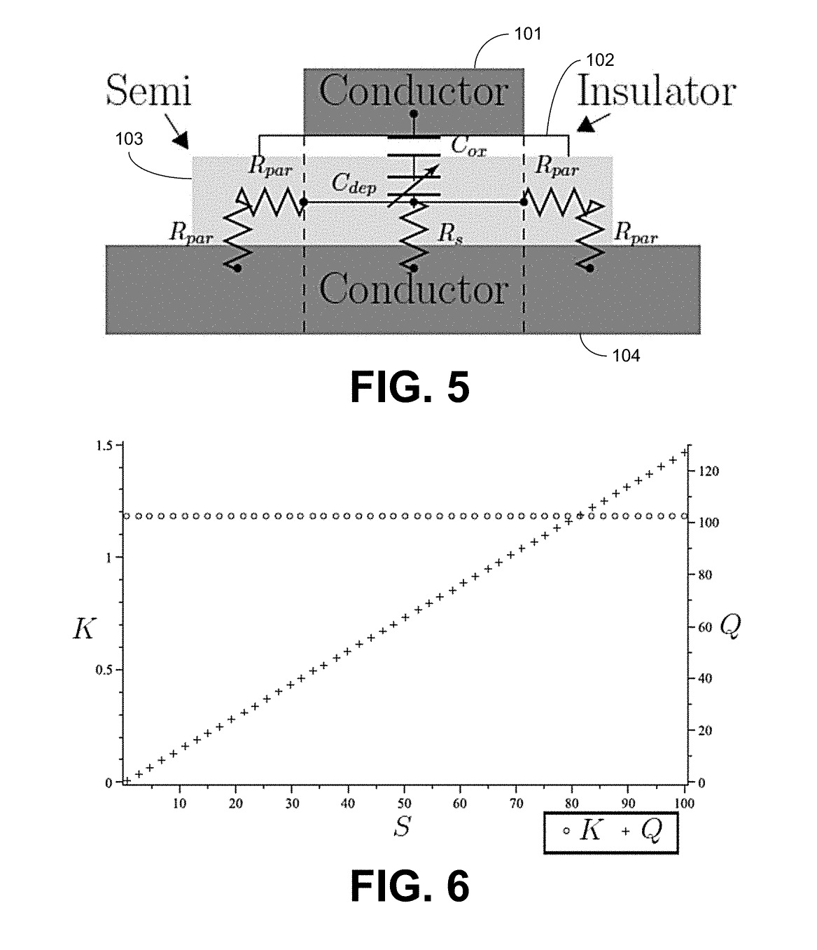

In this work, special care has to be devoted to minimizing Rₛ and maximizing the Q for a given K. However, there are some simplifications to Equation 4.1 through Equation 4.7 that can simplify this as shown below. First, the contact to the varactor can be similar to that of a TDM varactor. As illustrated in the lumped element model in FIG. 5, there is a top gate 101 and a bottom gate 104 that have the active component 103 of the varactor sandwiched between them. This means that the area term for Cₒₓ, C_{variable} and R_{c} are the same terms in the simplest embodiment of the device. This results in the Q and K equations being determined by thicknesses, ∈, ρₛ, and ρ_{c}, as in Equations 4.8 through 4.14.

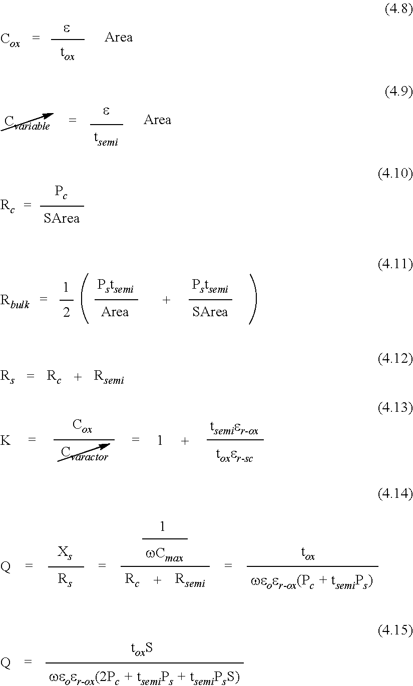

It is possible to further improve the Q of the device by increasing the bottom electrode 104 and the active region 103 as R_{c} which is governed by Equation 4.10. This will increase the quality of the device by further minimizing the contact resistance at the cost of the area using the scaling factor (S), as in Equation 4.15. For example, a 5×5 μm device's Q could ideally increase by as much as 500 percent by having an area of 15×10 μm, i.e. S of 5. Simply by adjusting this scaling factor the Q will ideally increase linearly for a given K at the cost of area, as shown by the plot of gain and quality factor of a MISM varactor in FIG. 6. K does not scale with S due to the fact that the capacitance is defined by the area underneath the smaller electrode 104 (neglecting fringe capacitance). However, increasing the area of the contact electrode 104 can lead to, e.g., increased parasitic capacitance which would impact the varactor's Q and K.

One approach to reducing R_{c} at the the varactor electrode contact area is to decrease the contact resistivity (ρ_{c}) of the R_{c} as much as possible. The AZO ρ_{c} can be as low as 2.95E-5 Ω-cm² and as high as 11.8E-5 Ω-cm² for Al and Au contacts respectively. To put this in perspective, ρ_{c} in CMOS and AJD style varactors is on the order of 1E-7 Ω-cm² to 1E-8 Ω-cm². At first this appears to be a major disadvantage of the current topology, especially as the doping concentration is reduced to increase K of the devices. However, the bulk material can afford to be very thin due to the required depletion depth which help keeps the Rₛ of the semiconductor low. CMOS varactors have very low ρ_{c}. They suffer from their performance being degraded by the Channel Resistance (R_{chan}) to the source/drain of the device. These lengths are defined by the minimum gate length of the CMOS technology node being used and while the R_{c} is low, the device is dominated by the ρₛ of the channel. This combines to be a significantly larger Rₛ than this work, especially when area used by the device is factored into the equation.

The improvements in this work is that this “channel length” is no longer in the lateral direction but oriented vertically between the top and bottom gate of the electrode and as mentioned above can be further reduced by over sizing the electrode that is in direct contact with the bulk of the varactor. This is a trait shared by the AJD and why AJDs have very high Qs, especially hyper-abrupt AJDs. Furthermore, the MISM varactor's ρₛ can actually meet or exceed that of degenerately doped devices ρ_{c}, 9E-9 Ω-cm² for n+Si, by utilizing a thin (<1 nm) TiO₂ layer. This TiO₂ layer effectively lowers the E_{g} and unpins the Fermi level of the device. It was deposited in this work using an ALD process while depositing the oxide and semiconductor layers. Another benefit is that due to the thickness of the TiO₂ layer direct tunneling dominates the current through the contact. However, unlike this work, AJD varactors cannot be integrated onto a CMOS process node as they require temperatures in excess of 400° C. in order to activate the dopants and transition from the amorphous to crystalline region. This fact eliminates AJD (along with MEMs, TDM, and pHEMT/HEMT SSCs) varactors from being integrated on-chip unless a flip-chip methodology is used.

Sub 400° C. processing allow the reduction of harmonics and enabling frequency-agile components. However, flip-chip methodology cannot offer a varactor directly at the “point of use.” This means that the circuits utilizing the varactor still have to go “off-chip” in order to electrically tune a device which then has to go back on-chip to react with the circuit or system. This work enables fabrication of these high Q devices as a back-end or front-end process to a traditional CMOS technology node as this work utilizes a sub 160° C. processes. In fact, the varactor can be small enough to be integrated directly on small via, gate, source, drain or inductor/resistor terminal of the circuit if so desired. This allows the integration to be implemented using a one or two layer mask depending on the complexity of the final design.

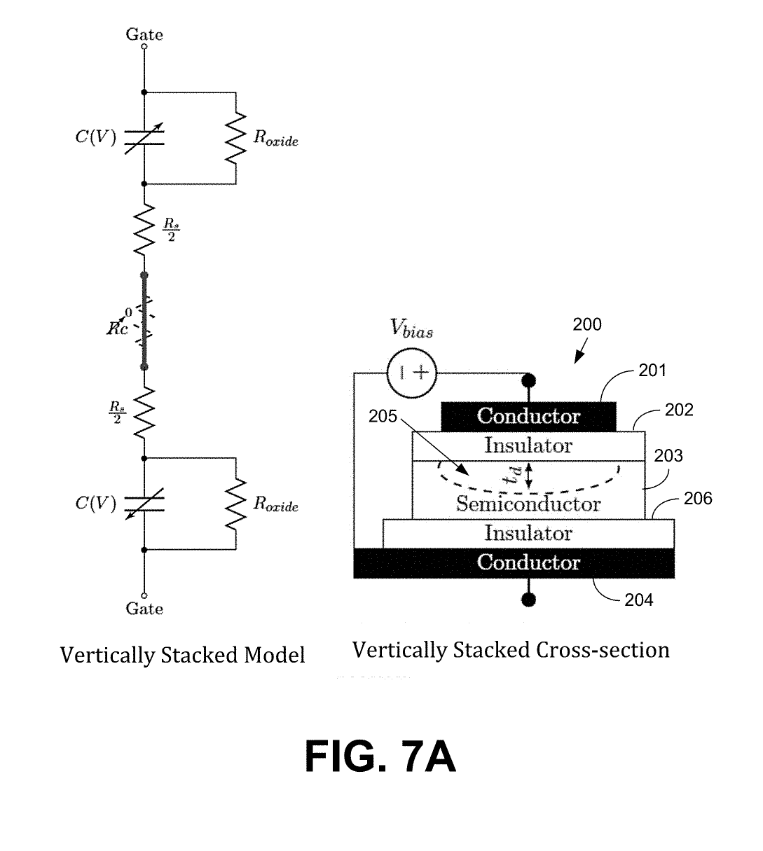

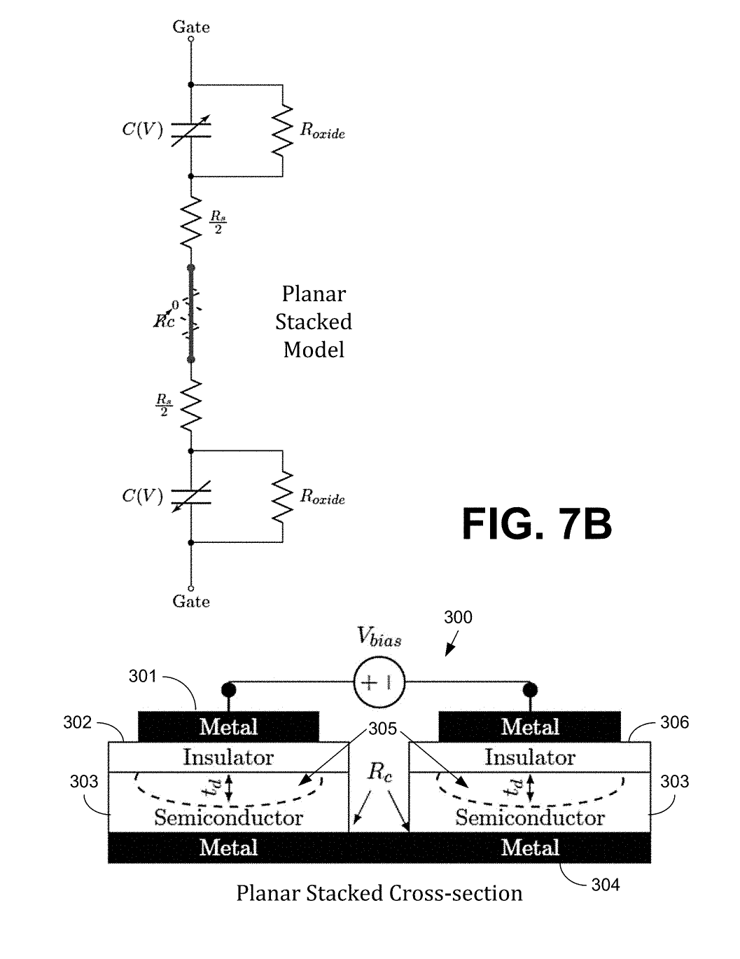

This work allows the vertical integration of a varactor stack on-chip, as illustrated in FIGS. 7A and 7B. Traditionally, MOS and diode varactors are built in planar configurations when integrated in a traditional CMOS process. That is, two or more varactors can be connected through planar interconnects. This doubles the R_{c} and increases the Rₛ of the varactor as there are now two regions which are in contact in addition to the series resistance added by the wire. By introducing a second oxide layer that isolates the bulk region of the MISM varactor, there is no longer an R_{c} and Equation 4.14 further simplifies to Equation 4.16.

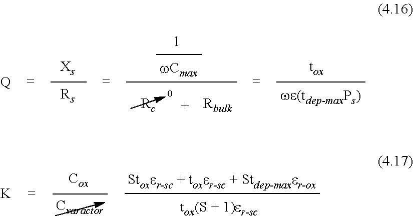

This creates another new topology MISIM varactor called a floating body varactor (FBV) due to the “electrically floating semiconductor body.” The FBV traps a thin semiconductor material between two insulators, which in its simplest form includes two MISM varactors stacked in a vertical topology as shown in FIG. 7A, or a planar topology as shown in FIG. 7B.

The vertically stacked FBV 200 of FIG. 7A includes a conductor layer 201 disposed on an insulator layer 202, which is itself disposed on a semiconductor layer 203 that is disposed on another insulator layer 206 disposed on another conductor layer 204. The planar FBV 300 of FIG. 7B includes a conductor layer 301 disposed on an insulator layer 302, which is itself disposed on a semiconductor layer 303 that is disposed on a base conductor layer 304. Another conductor layer is disposed on another insulator layer 306, which is itself disposed on another semiconductor layer 303 that is disposed on the base conductor layer 304. Following the previous MISM naming convention this could also be called a Metal Insulator Semiconductor Insulator Metal (MISIM) varactor, with layers 205 and 305 once again being the depletion/accumulation region, or any plurality thereof with or without additional metal layers in-between and the materials could be any thickness that the designer deems advantageous (not limited to all layers being the same thickness). This eliminates a contact resistance to the semiconductor region which can be a major cause of series resistance that impacts the Quality factor of the device. A plurality of these devices can be stacked vertically or in a planar fashion based on the designers needs in the system.

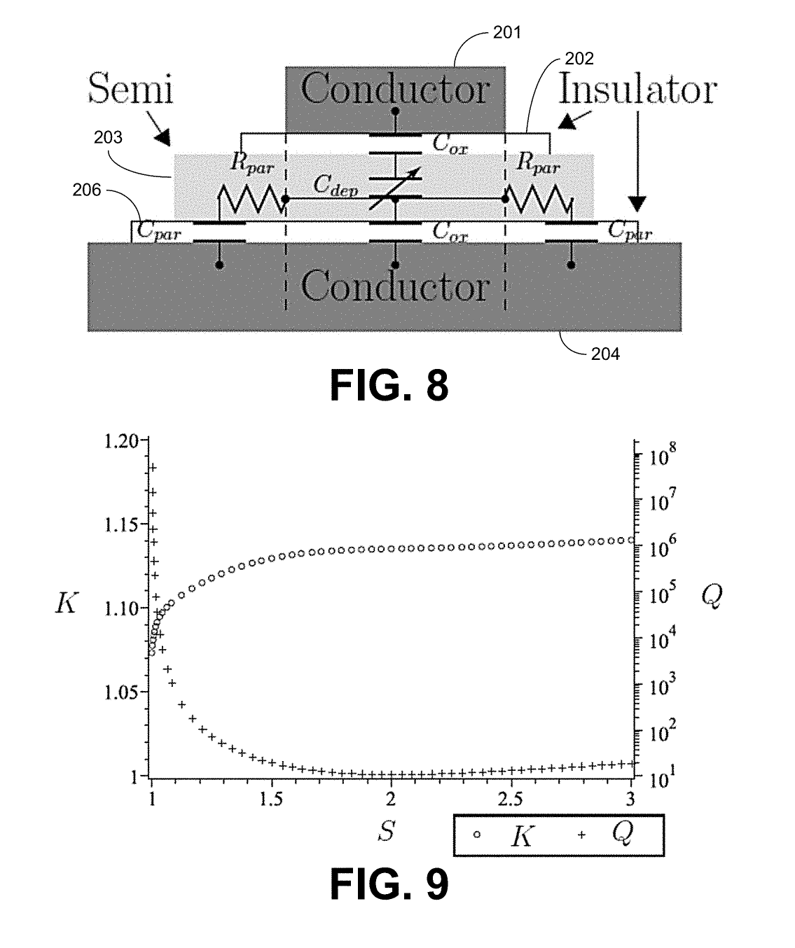

As illustrated in the lumped element model in FIG. 8, the varactor 200 can be viewed as putting a fixed capacitor in series with the FBV. This topology dramatically increases, by multiple orders of magnitude, the potential Q value to that of a near ideal varactor. FIG. 9 illustrates the gain and quality factor for a “vertically stacked” FBV 200. For an S of 1 (where the top electrode 201 has the same area as the bottom electrode 204) that the K is exactly half of FIG. 6 using the same material properties. However, the Q value of the FBV improves from the 1.27 shown in FIG. 6, for the MISM varactor 100, to 2.3E-6 for a S of 1, as shown in FIG. 9. The Q can grow to over eight orders of magnitude difference with an increasing S while K approaches the MISM's maximum gain, as shown in FIG. 9.

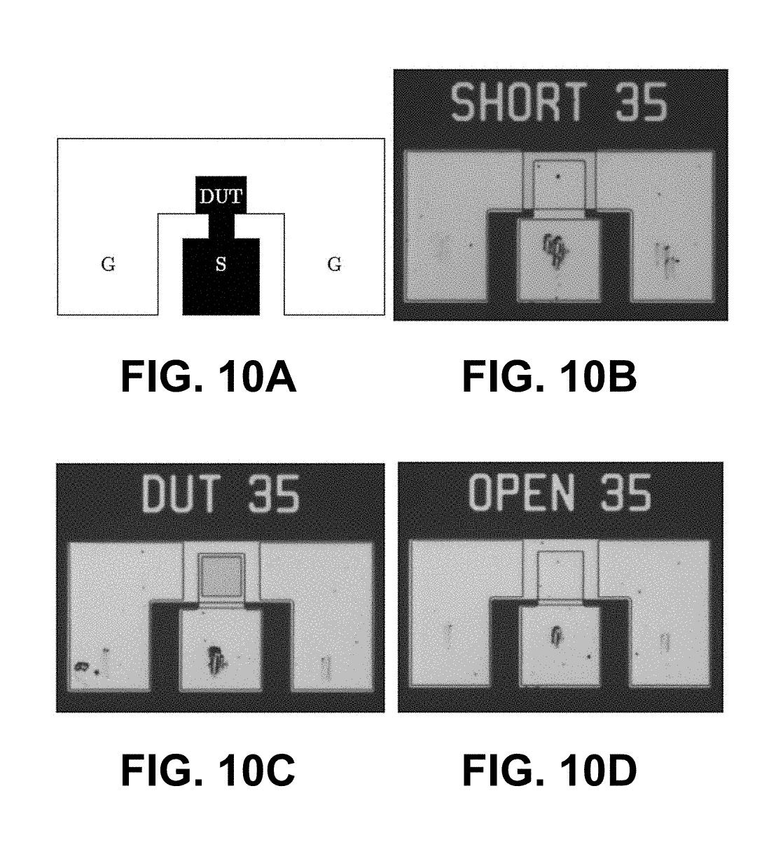

Second Generation devices were designed and fabricated to further test the practical application of this technology. The basic set of device masks were designed to build MISM and the FBV. The methodologies used for fabrication were similar to the methods previously discussed. However, the device masks were changed in order to take advantage of a simpler 1-port test methodology for CPW. FIG. 10A graphically illustrates the GSG (ground signal ground) CPW probe structure used to test the varactors. FIGS. 10B, 10C and 10D are images of a short structure, a device under test, and an open structure that were used during testing. This allowed for directly probing the varactors without mechanical failures due to physically damaging the devices upon landing the GSG probe. This also ensured that adequate contact was being made between the test equipment and the DUT. Since the devices were tested using a 1-port model, the de-embedding methodology of a short open load through (SOLT) for a 2-port model can simply be reduced to a short open load (SOL) to a SOLT. The specific de-embedding techniques used in these measurements are capable of measuring even small capacitances out to 100+GHz.

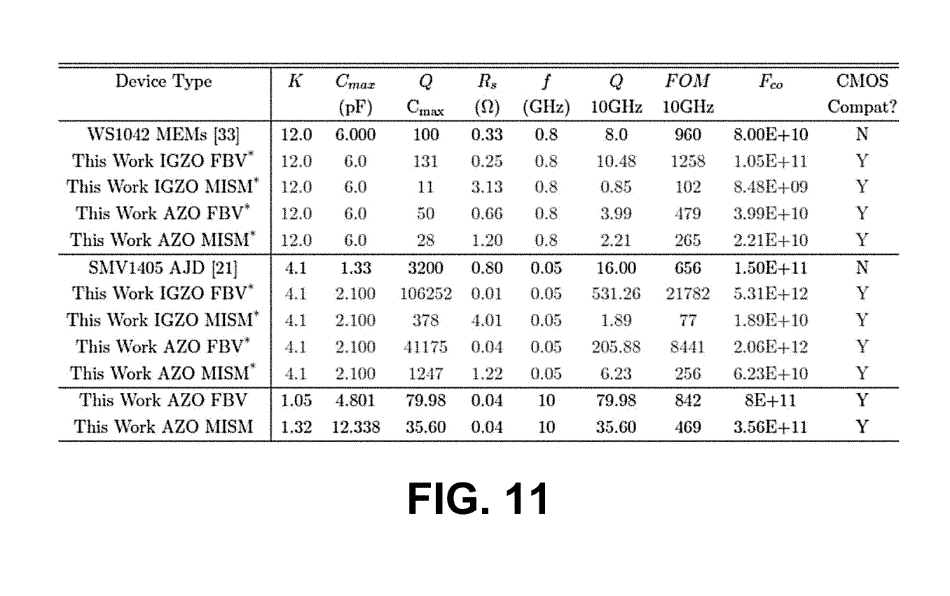

These final round of devices were fabricated using ALD of AZO as the semiconductor and ALD of Al₂O₃ as the oxide layer. HfO₂ and IGZO were not available in the ALD tool at the time of this work. These materials were deposited at the same time without breaking vacuum. Additionally, these layers were deposited directly on a TiAu layer, where Au was in direct contact with the Al₂O₃ and Ti was used as an adhesion layer, stack which minimized intra-layer oxides in the device. The measured results yielded Qs in the 1000s for low frequencies and Q up to 80 for 10 GHz as shown in the table of FIG. 11. Simulation model results are indicated by an asterisk (*). This is a notable improvement over the preceding designs; however, the K of the device was only 1.32:1 in the best case measurement. Hall effect measurements were taken and the AZO doping concentrations were found to be 3.01E+20 cm⁻³ which yield approximately the same gain as what was to be expected from the Verilog-A modeling of 3.25E+20 cm⁻³.

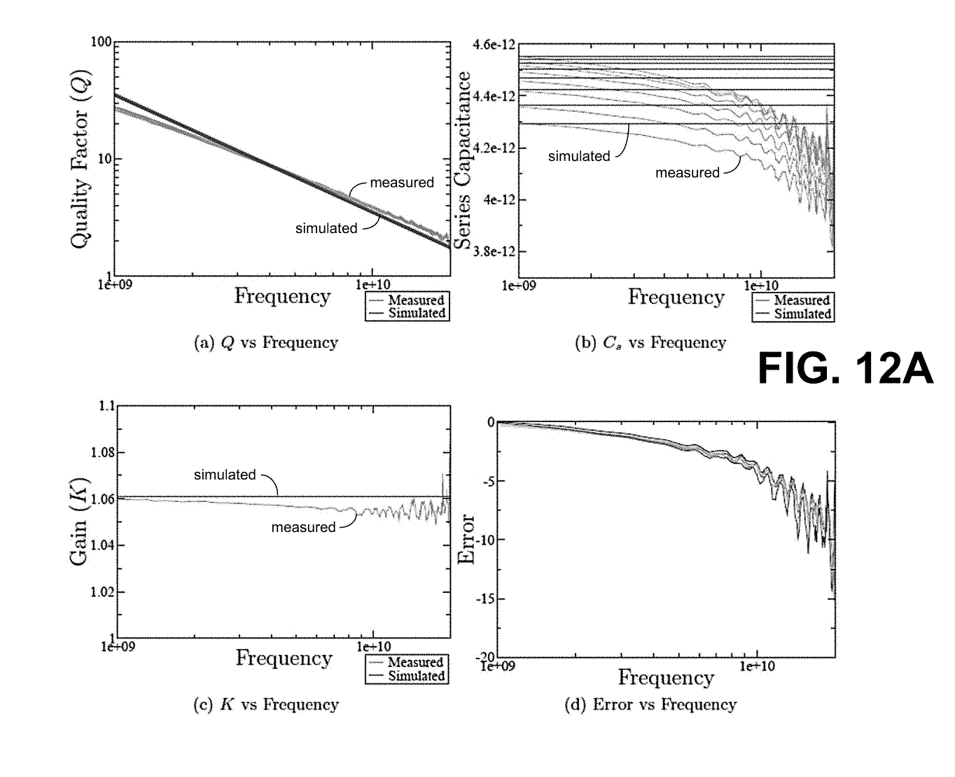

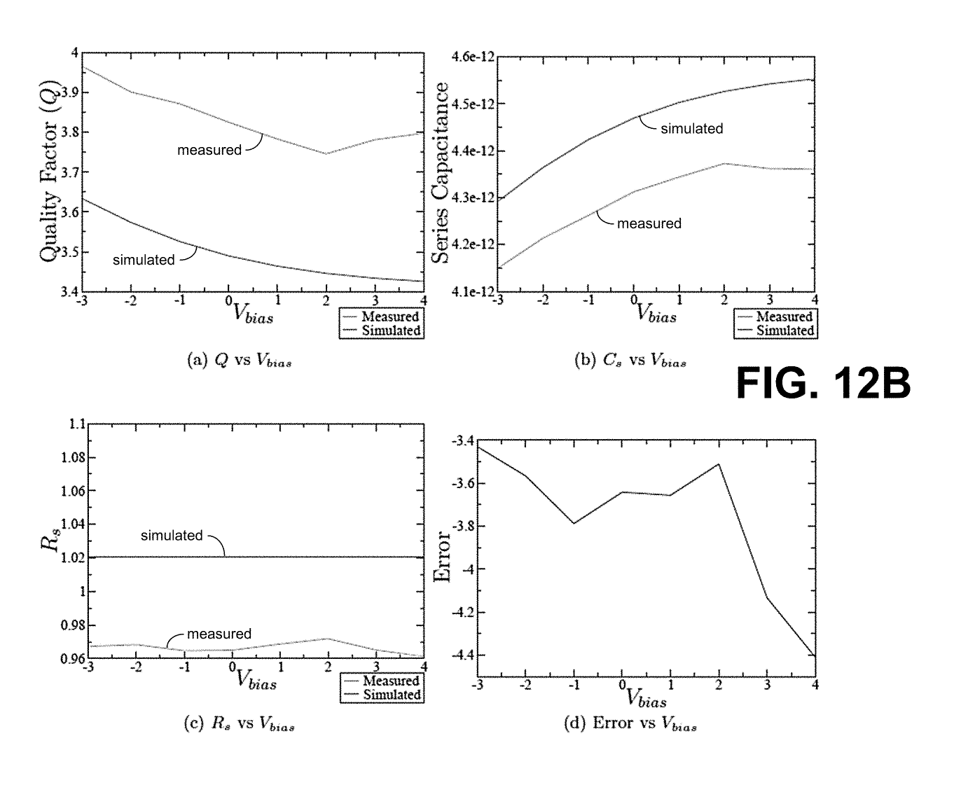

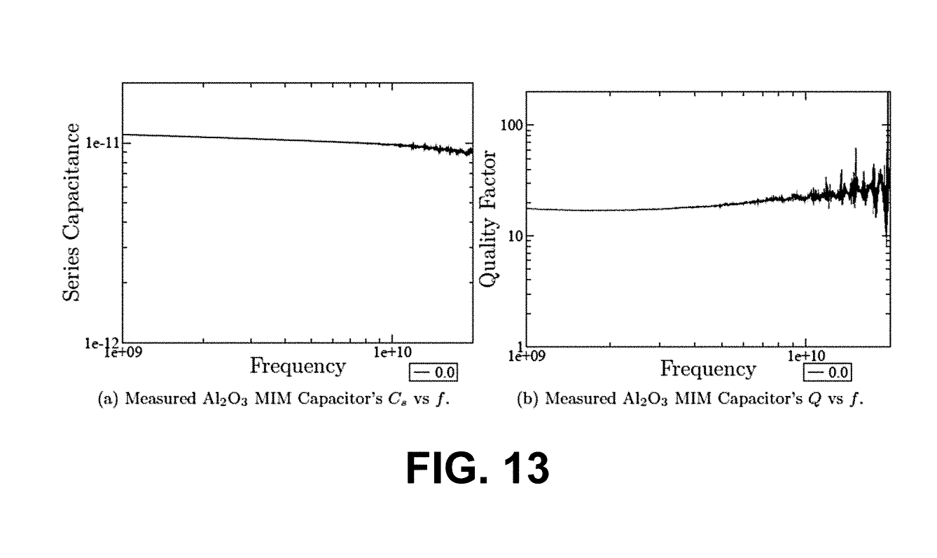

When the rest of the device parameters were entered back into the Verilog-A model, it yielded matching results that gave very similar device characteristics and performance. The K and the capacitance had the same general trend and were within 10 percent of the measured values, as shown in FIGS. 12A and 12B. FIG. 12A illustrates the AZO MISM simulated vs. measured varactor results with respect to frequency and FIG. 12B illustrates the AZO MISM simulated vs. measured varactor results with respect to applied bias (V_{bias}). However, Q wasn't nearly as good as we expected from the fabricated results. This may be attributed in part to the fabrication process.

Measurements were performed on a VNA (voltage network analyzer) and de-embedded using Octave scripts which implemented a de-embedding technique. However, it should be noted that VNAs and GSG probes can introduce measurement errors even with the most perfect de-embedding. Agilent, makers of the VNA, state that there is an approximate 2-3 degrees of phase error and the GSG probes used can insert as much as 2 degrees of phase error. This gives a total phase error of around 5 degrees. This is especially true for small capacitive loads that have very small series resistances because as the 4) in the magnitude and phase vector approach 90 degrees, the tan function becomes indeterminate. The sensitivity of the real component, Equation 4.18, based on the phase angle yields Equation 4.19.

Re=|Z|cos(θ) (4.18)

ζ_{φ}^{Re}=−φ tan(φ) (4.19)

If the polar coordinates of the modeled varactor results in Phase Angle (φ) are greater than 85 degrees, as shown in the table of FIG. 11. This translates into a minimum accurate sensitivity of the measurement equipment of 0.33Ω. Solving the same set of equations at 1 GHz gives a minimum sensitivity of 3.3Ω for the same device.

It is expected that the latest fabricated devices fall well below the minimum sensitivity. This is noticed by an increase in Q that can be partially attributed to the increase in the VNA's ability to more accurately extract the Rₛ with the increase in frequency as well as the decrease in measured capacitance. This was tested by fabricating an Al₂O₃ MIM capacitor using the same procedures as the MISM varactor. FIG. 12 shows the measured results from the MIM Al₂O₃ capacitor on a VNA. The K was 1, the capacitance of the oxide was 9.8 pF, Q of 21.6 which yielded an Rₛ of 0.07 at 10 GHz. There were several varactors that had the same order of magnitude of Rₛ as the Al₂O₃ control wafer. Thus, the final generation of FBV and MISM that was optimized with TiO₂ falls far below this sensitivity threshold. To determine the true Q of these devices, the capacitance will have to be significantly increased to reduce the phase angle or increase the testing frequency of the devices.

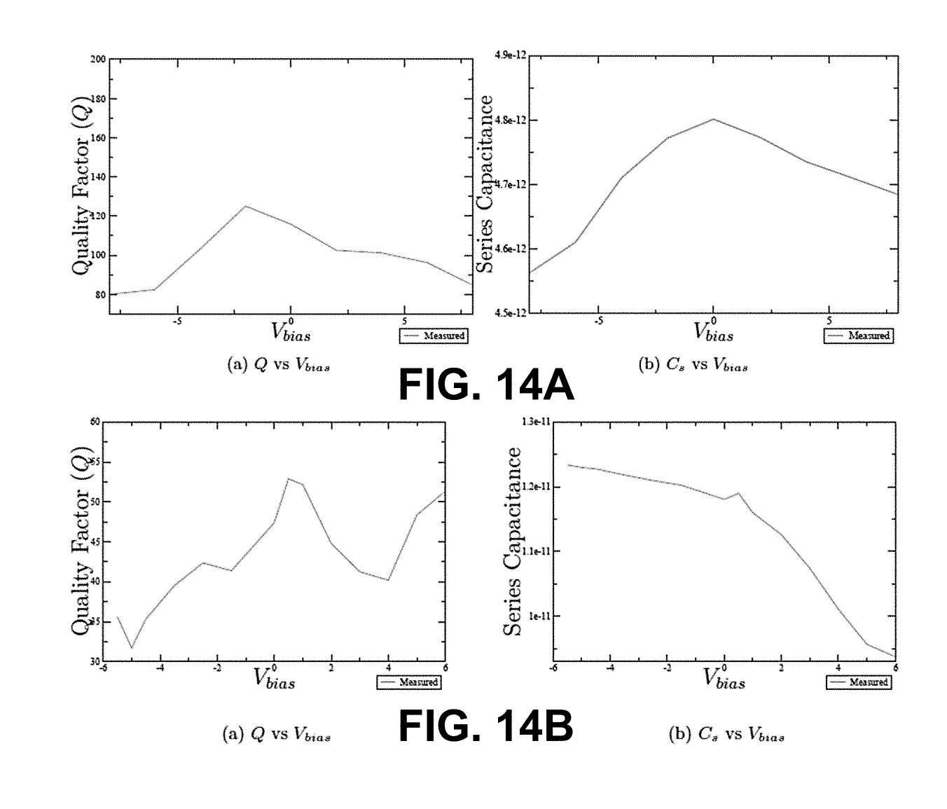

Using the developed models, FBV and MISM devices were created that matched the K, Cₘₐₓ and Cₘᵢₙ of commercially available products from Skyworks Solutions and WSpry. FIG. 14A shows the AZO FBV simulated and measured varactor results vs. applied bias (V_{bias}). The measured FBV having a Q of 80 is between the two commercially available devices FOM. Next, the minimum Q was extracted from the model to compare in the table of FIG. 11. The FBV can extend past the current state of the art in just the key performance metrics of the device, plus the ability to remove the traditional interconnect further increasing frequency agelessness and Q of the device with further process development. The MISM varactor may be further improved based upon the values in the table of FIG. 11, which assume the ρ_{c} from a non-optimized contact area. FIG. 14B shows the AZO MISM simulated and measured varactor results vs. applied bias (V_{bias}). Through the inclusion of TiO₂ or other methods as they already have measured FOM of the MISM varactor at 469 and a measured Q of 35 at 10 GHz.

Apart from the topology of the MISM and FBV mentioned above, there are improvements to the devices from a processing standpoint. For example, materials can be used that can be deposited at a lower temperature (but not limited to low temperature materials) enabling the devices to be transparent, flexible, stretchable, polymers, and/or integrated as a back end process. The designer can pick and choose the materials that are best suited for the design and also is afforded the option of integrating these devices as a front or backend process. The process for producing a varactor can be a backend process or a frontend process. Common materials such as AZO, ITO, IGZO, SiO₂, HfO₂, AL₂O₃, TiO₂, Si, etc. can be used but should not be limited to that as the materials are simply a means to realize the core invention and will improve as technologies advance.

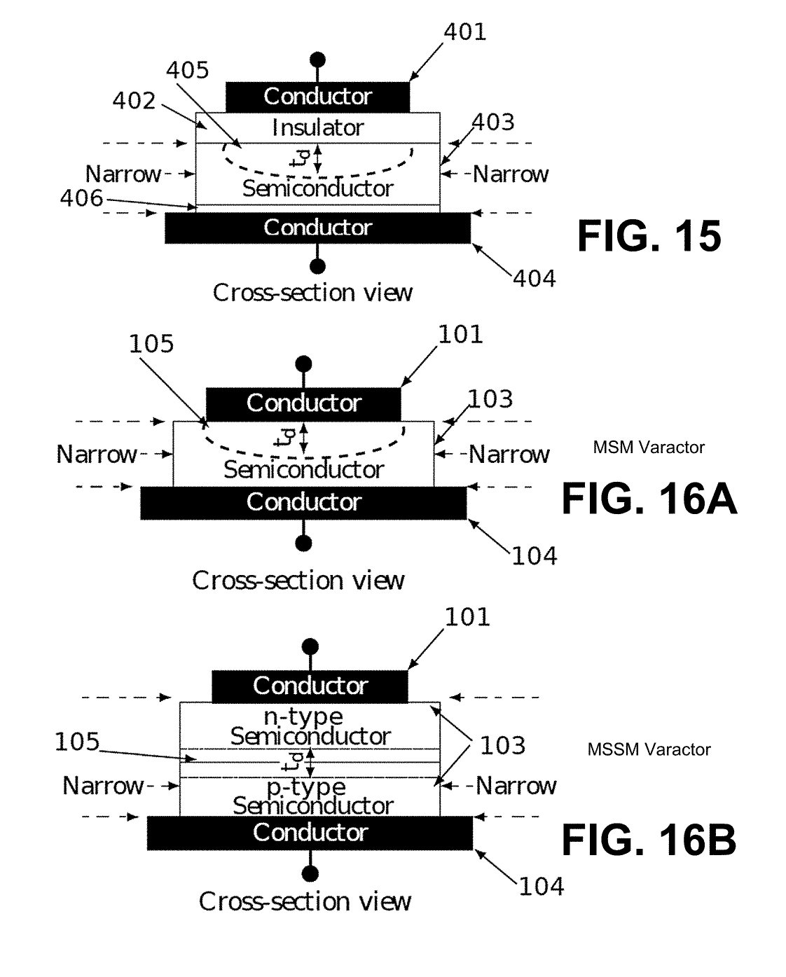

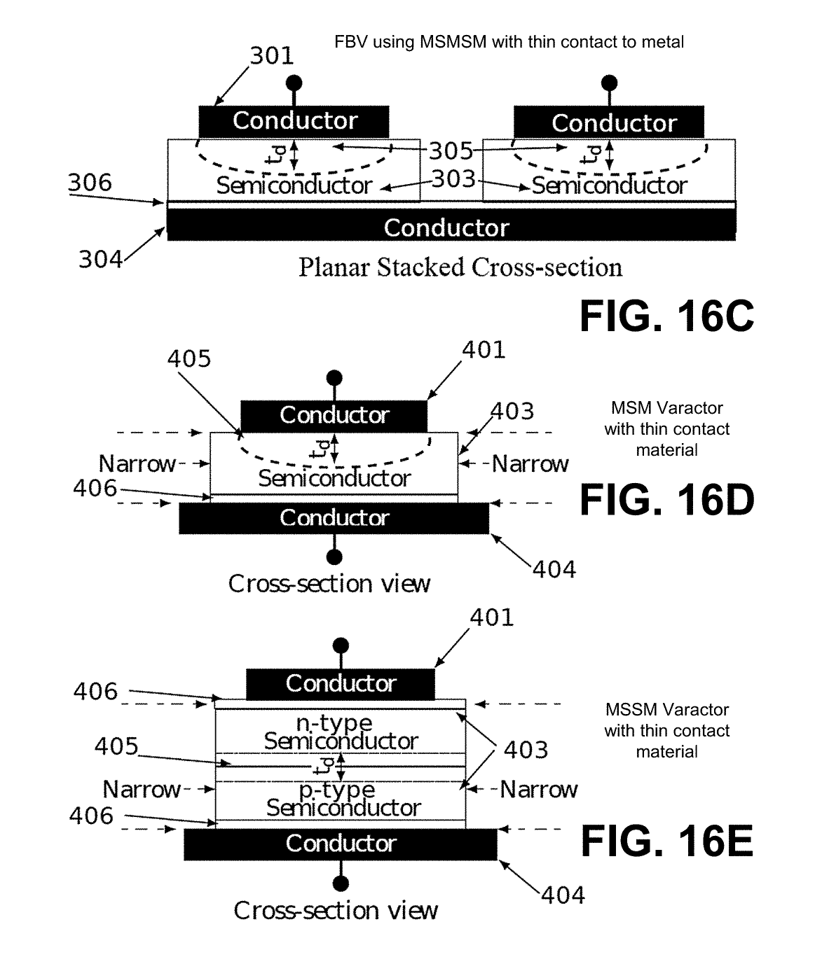

In addition to the materials mentioned above, improvements can be made to further reduce the series resistance through the application of a very thin film (e.g., less than 2 nm) that can significantly reduce the contact resistance, as illustrated in FIG. 15. FIG. 15 shows the varactor with the Metal Insulator Semiconductor Metal and thin material region 406 varactor with depletion/accumulation region as 405. As illustrated the MISM varactor includes a metal conductor layer 401 disposed on an insulator layer 402, which is itself disposed on a semiconductor layer 403 that is disposed on the thin material region 406 disposed on another metal conductor layer 404. For example, if a designer places a thin film of an insulator such as (but not limited to) TiO₂ between the semiconductor region 403 and the second conductor 404, then a reduced resistance can be created. The electrons can travel through the this material through various methods such as tunneling or via the conduction bands of the material lowering or eliminating the barrier to travel between materials. This method can also be applied to a diode style varactor to reduce or eliminate the contact resistance. FIG. 16A-16D illustrate different styles of diodes using this thin film to reduce contact resistance. The method is applicable for most any style diode such as Shockley and PN Junction diodes, but should not only be limited to these. FIG. 16A shows a very simple thin narrow style varactor similar to that of FIG. 1 with the insulator, 102, removed to form a metal semiconductor junction. FIG. 16B shows the same method when applied to a PN Junction diode. FIG. 16C shows the same style varactor as in FIG. 7B where the insulator, 302 and 306, is once again removed creating a metal semiconductor junction. Furthermore, FIG. 16C adds a thin film to reduce the series resistance as mentioned above, 706. FIG. 16D is comparable to FIG. 15 where the insulator, 402, is removed to form a metal semiconductor junction with a thin film reducing the series resistance once again. FIG. 16E shows the same scenario as FIG. 16D but for a PN Junction style diode.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

At least the following is claimed:

1. A varactor, comprising:
a first conductive electrode;
a semiconductor formed over the conductive electrode;
an insulator formed over the semiconductor; and
a second conductive electrode formed over the insulator.

2. The varactor of claim 1, further comprising a thin insulator formed between the first conductive electrode and the semiconductor.

3. The varactor of claim 2, where the thin insulator is less than 2 nanometers in thickness.

4. The varactor of claim 2, where the insulator is a TiO₂ dielectric.

5. The varactor of claim 1, where the semiconductor material is AZO, IGZO, or Silicon.

6. The varactor of claim 1, where the varactor is deposited on a transparent substrate.

7. The varactor of claim 1, where the varactor is deposited on a flexible and/or rigid substrate.

8. A varactor, comprising:
a semiconductor formed over a first insulator or a base conductive electrode;
a second insulator formed over the semiconductor; and
a second conductive electrode formed over the insulator.

9. The varactor of claim 8, further comprising:
a first conductive electrode; and
the first insulator formed over the first conductive electrode.

10. The varactor of claim 8, further comprising:
a second semiconductor formed over the base conductive electrode;
the first insulator formed over the second semiconductor; and
a first conductive electrode formed over the first insulator.

11. The varactor of claim 8, where the semiconductor material is AZO, IGZO, or Silicon.

12. The varactor of claim 8, where deposited on a transparent and/or flexible and/or rigid substrate.

13. The varactor of claim 8, where the varactor is deposited on hard substrate.

14. A varactor, comprising:
a conductive electrode;
a thin material formed over the conductive electrode; the thin material configured to reduce the series resistance of the varactor; and
a semiconductor formed over the thin material.

15. The varactor of claim 14, where the thin material is an insulator that is less than 2 nanometers in thickness.

16. The varactor of claim 14, where the thin material is less than 2 nanometers in thickness.

17. The varactor of claim 14, comprising an insulator formed over the semiconductor, where the insulator is a TiO2 dielectric.

18. The varactor of claim 14, wherein the varactor is communicatively coupled with digital or analog circuitry.

19. The varactor of claim 14, wherein an electronic system comprises the varactor and the digital or analog circuitry.
